(19) United States
(12) Patent Application Publication
(10) Pub. No.: US 2025/0337999 A1
(43) Pub. Date: Oct. 30, 2025

(54) SOLID-STATE IMAGING APPARATUS, IMAGING APPARATUS, AND ELECTRONIC APPARATUS

(71) Applicant: SONY SEMICONDUCTOR SOLUTIONS CORPORATION, KANAGAWA (JP)

(72) Inventors: CHIAKI SHIBUYA, KANAGAWA (JP); KATSUJI KIMURA, KANAGAWA (JP); MASASHI NAKAMURA, KANAGAWA (JP); FUMIHIKO HANZAWA, KANAGAWA (JP); DAICHI MURAKAMI, KANAGAWA (JP); HARUKI TAKEUCHI, KANAGAWA (JP)

(21) Appl. No.: 18/849,498

(22) PCT Filed: Mar. 13, 2023
(86) PCT No.: PCT/JP2023/009498

§ 371 Date: Sep. 21, 2024

(30) Foreign Application Priority Data
Mar. 29, 2022 (JP) 2022-053267

(51) Int. Cl. H04N 23/55; G02B 13/14

(52) U.S. Cl. CPC H04N 23/55; G02B 13/14

(57) ABSTRACT

The present disclosure relates to a solid-state imaging apparatus, an imaging apparatus, and an electronic apparatus capable of achieving downsizing and height reduction of an apparatus configuration. There are provided a solid-state imaging element configured to capture an image including a pixel signal corresponding to a light amount of incident light, and a lens group including a plurality of lenses configured to condense the incident light and form an image on an imaging surface of the solid-state imaging element, and at least one of the plurality of lenses constituting the lens group is a visible light cut lens configured to cut a visible light ray from the incident light and transmit the incident light. The present disclosure can be applied to a solid-state imaging apparatus.

### TECHNICAL FIELD

The present disclosure relates to a solid-state imaging apparatus, an imaging apparatus, and an electronic apparatus, and especially relates to a solid-state imaging apparatus, imaging apparatus, and an electronic apparatus capable of achieving downsizing and height reduction of an apparatus configuration.

### BACKGROUND ART

In recent years, high-pixelization, downsizing, and height reduction of a solid-state imaging apparatus used in a mobile terminal device with a camera, a digital still camera, and the like have been progressing.

With high-pixelization and downsizing of a camera, a solid-state imaging apparatus in which a lens and a solid-state imaging element are configured on an optical axis and an infrared cut filter is disposed near the lens has become common (see, for example, Patent Documents 1 and 2).

In addition, there has been proposed a technique in which a dye that absorbs infrared light is mixed into an optical film or a plate material to configure an infrared light cut filter (Patent Documents 3 to 5).

### CITATION LIST

### Patent Document

Patent Document 1: Japanese Patent Application Laid-Open No. 2018-200423
Patent Document 2: Japanese Patent Application Laid-Open No. 2012-098429
Patent Document 3: Japanese Patent Application Laid-Open No. 2020-134835
Patent Document 4: Japanese Patent Application Laid-Open No. H8-043603
Patent Document 5: WO 2014/080561 A1

### SUMMARY OF THE INVENTION

### Problems to be Solved by the Invention

However, in the case of the inventions described in Patent Documents 1 to 4 described above, many glass base materials of an infrared cut filter and a band pass filter (BPF) have a size of 0.2 mm or more, and this configuration prevents height reduction.

The present disclosure has been made in view of such a situation, and in particular, made to be capable of achieving downsizing and height reduction of an apparatus configuration related to imaging.

### Solutions to Problems

A solid-state imaging apparatus, an imaging apparatus, and an electronic apparatus according to one aspect of the present disclosure are a solid-state imaging apparatus, an imaging apparatus, and an electronic apparatus that include a solid-state imaging element configured to capture an image including a pixel signal corresponding to a light amount of incident light; and a lens group including a plurality of lenses configured to condense the incident light and form an image on an imaging surface of the solid-state imaging element, and at least one of the plurality of lenses constituting the lens group is a visible light cut lens configured to cut a visible light ray from the incident light and transmit the incident light.

In one aspect of the present disclosure, at least one of a plurality of lenses constituting a lens group including the plurality of lenses configured to condense incident light and form an image on an imaging surface of a solid-state imaging element configured to capture an image including a pixel signal corresponding to a light amount of the incident light, is a visible light cut lens configured to cut a visible light ray from the incident light and transmit the incident light.

### BRIEF DESCRIPTION OF DRAWINGS

FIG. 1 is a diagram for describing a configuration example of a solid-state imaging apparatus in a case where a BPF is provided.

FIG. 2 is a diagram for describing that a frequency band of transmitted light shifts to a short wavelength side according to an angle of incidence.

FIG. 3 is a graph for describing that a frequency band of transmitted light shifts to a short wavelength side according to an angle of incidence.

FIG. 4 is a diagram for describing a configuration example of a solid-state imaging apparatus of the present disclosure.

FIG. 5 is a graph for describing transmission characteristics of respective lenses constituting a lens group.

FIG. 6 is a diagram for describing shapes serving as conditions for a dye lens.

FIG. 7 is a diagram for describing conditions for a dye lens.

FIG. 8 is a graph for describing a relationship between a lens thickness and a transmission characteristic.

FIG. 9 is a diagram for describing conditions for a dye lens.

FIG. 10 is a diagram for describing a configuration example of a solid-state imaging apparatus with a BPF and including a lens group including two lenses.

FIG. 11 is a diagram for describing a configuration example of a solid-state imaging apparatus of the present disclosure that is without a BPF, includes a lens group including two lenses, and forms the same image as an image in FIG. 10.

FIG. 12 is a table for describing conditions for each lens in the lens group in FIG. 11 to becomes a dye lens.

FIG. 13 is a table for describing an effect of the solid-state imaging apparatus in FIG. 11.

FIG. 14 is a diagram for describing a configuration example of a solid-state imaging apparatus with a BPF and including a lens group including three lenses.

FIG. 15 is a diagram for describing a configuration example of a solid-state imaging apparatus of the present disclosure that is without a BPF, includes a lens group including three lenses, and forms the same image as an image in FIG. 14.

FIG. 16 is a table for describing conditions for each lens in the lens group in FIG. 15 to become a dye lens.

FIG. 17 is a table for describing an effect of the solid-state imaging apparatus in FIG. 15.

FIG. 18 is a diagram for describing a configuration example of a solid-state imaging apparatus with a BPF and including a lens group including three lenses.

FIG. 19 is a diagram for describing a configuration example of a solid-state imaging apparatus of the present disclosure that is without a BPF, includes a lens group including four lenses, and forms an image substantially the same as an image in FIG. 18.

FIG. 20 is a table for describing conditions for each lens in the lens group in FIG. 19 to become a dye lens.

FIG. 21 is a table for describing an effect of the solid-state imaging apparatus in FIG. 19.

FIG. 22 is a diagram for describing a configuration example of a solid-state imaging apparatus with a BPF and including a lens group including five lenses.

FIG. 23 is a diagram for describing a configuration example of a solid-state imaging apparatus of the present disclosure that is without a BPF, includes a lens group including five lenses, and forms the same image as an image in FIG. 22.

FIG. 24 is a table for describing conditions for each lens in the lens group in FIG. 23 to become a dye lens.

FIG. 25 is a table for describing an effect of the solid-state imaging apparatus in FIG. 23.

FIG. 26 is a diagram for describing a modification example of the solid-state imaging apparatus of the present disclosure.

FIG. 27 is a block diagram illustrating a configuration example of an imaging apparatus as an electronic apparatus to which a camera module of the present disclosure is applied.

FIG. 28 is a diagram for describing a usage example of a camera module to which the technology of the present disclosure is applied.

### MODE FOR CARRYING OUT THE INVENTION

Hereinafter, a preferred embodiment of the present disclosure will be described in detail with reference to the accompanying drawings. Note that, in the present specification and drawings, components having substantially the same functional configuration are denoted by the same reference signs, and redundant description is omitted.

Hereinafter, modes for carrying out the present technology will be described. The description is given in the following order.
1. Configuration Example of Solid-state Imaging Apparatus in Case Where BPF Is Provided
2. Preferred Embodiment
3. Modification Examples
4. Application to Electronic Apparatus
5. Usage Example of Solid-state Imaging Apparatus

### 1. Configuration Example of Solid-State Imaging Apparatus in Case where BPF is Provided

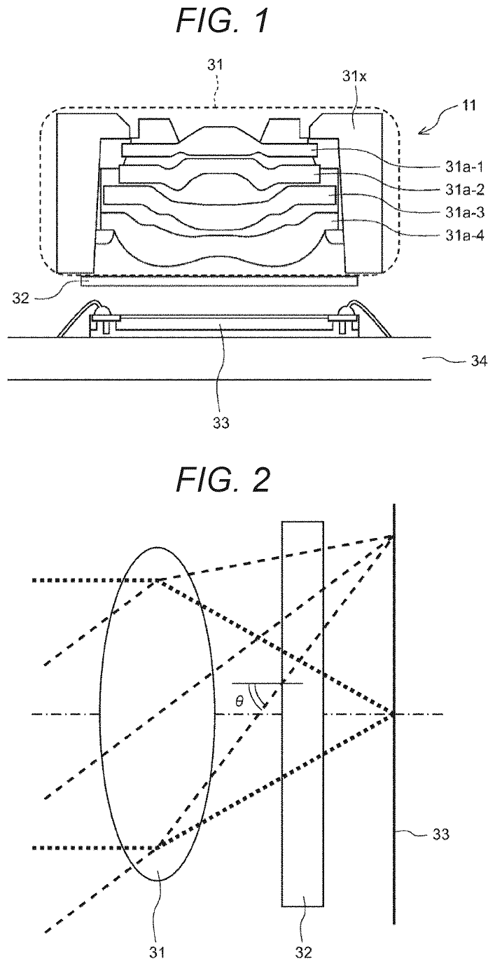

Before a configuration of a solid-state imaging apparatus of the present disclosure will be described, first, a configuration example of a solid-state imaging apparatus including a BPF will be described with reference to FIG. 1. Note that FIG. 1 is a side cross-sectional view of the solid-state imaging apparatus.

A solid-state imaging apparatus 11 in FIG. 1 includes a lens group 31, a band pass filter (BPF) 32, a solid-state imaging element 33, and a substrate 34. The solid-state imaging apparatus 11 in FIG. 1 has a configuration in which the lens group 31, the BPF 32, the solid-state imaging element 33, and the substrate 34 are sequentially stacked in this order in an incident direction of incident light that is a downward direction from the top in the figure.

The lens group 31 includes a plurality of lenses 31a-1 to 31a-4 provided in a case 31x, and condenses the incident light from above in the figure on an imaging surface of the solid-state imaging element 33 to form an image.

The BPF 32 is, for example, a glass substrate coated with a transmission film configured to cut visible light, or the like, and the BPF 32 is configured to cut visible light from incident light transmitted through the lens group 31 and transmit near-infrared light.

The solid-state imaging element 33 is an image sensor including a so-called complementary metal oxide semiconductor (CMOS), a charge coupled device (CCD), or the like and is fixed on the substrate 34 in an electrically connected state. The solid-state imaging element 33 includes a plurality of pixels (not illustrated) disposed in an array, generates a pixel signal corresponding to a light amount of the incident light condensed and incident from above in the figure via the lens group 31 and the BPF 32 in units of pixels, and outputs the pixel signal as an image signa to the outside via the substrate 34.

With a configuration of the solid-state imaging apparatus 11 as illustrated in FIG. 1, the BPF 32 is provided on the solid-state imaging element 33. Therefore, it is possible to capture an image including near-infrared light with visible light cut from the incident light.

However, although the BPF 32 has a configuration in which a glass substrate is coded with a transmission film configured to cut visible light and transmit near-infrared light, the glass substrate has a thickness of about 0.2 mm at the thinnest and has been an element that prevents height reduction of the solid-state imaging apparatus 11.

In addition, although the BPF 32 has the configuration in which the glass substrate is coated with the transmission film configured to cut visible light and transmits near-infrared light, the coating has a configuration in which a plurality of transmission films is stacked. Thus, if an angle of incidence of the incident light increases, refraction at a boundary of the transmission film is repeated, so that a transmission characteristic changes.

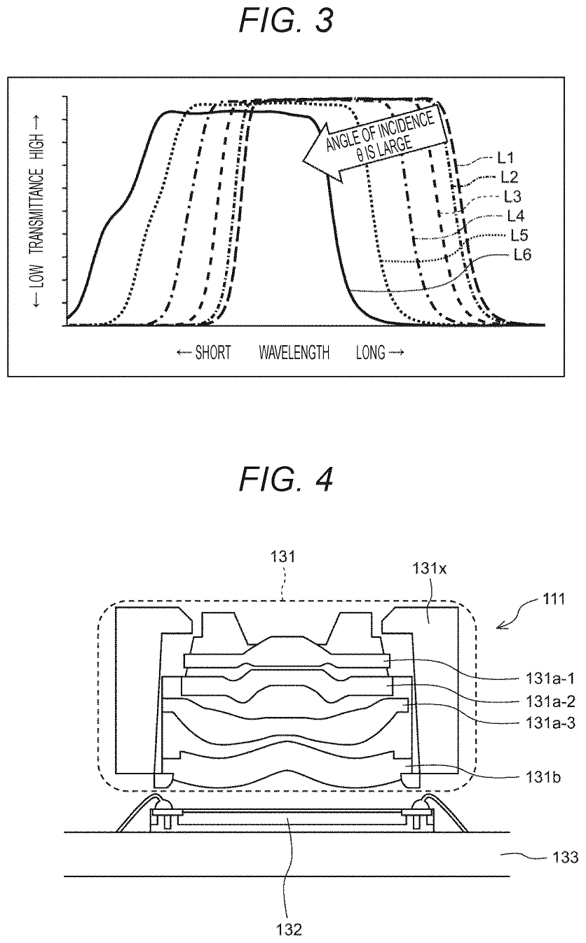

More specifically, in a case where the lens group 31 is assumed to be one lens, for example, as illustrated in FIG. 2, when the incident light transmitted through the lens group 31 is incident on the BPF 32 at an angle of incidence θ, a transmission characteristic of the transmitted light for each incident angle θ has a relationship as illustrated in FIG. 3.

FIG. 3 illustrates a transmission characteristic of the BPF 32 with a horizontal axis representing a wavelength of the incident light and a vertical axis representing transmittance, and waveforms L1 to L6 are transmission characteristics corresponding to angles of incidence θ1 to θ6, respectively. In addition, the angles of incidence θ1 to θ6 satisfy θ1<θ2<θ3<θ4<θ5<θ6.

In other words, as the angle of incidence θ increases, a range of higher transmittance shifts to a short wavelength side as illustrated by an arrow in FIG. 3, and light having a wavelength substantially shorter than that of the incident light is transmitted.

Thus, the incident light shifts to a shorter wavelength band as the angle of incidence θ to the BPF 32 increases and becomes light of a color different from an actual color before being incident on the BPF 32, and sensitivity in an originally necessary wavelength band deteriorates in the solid-state imaging element 33.

For this reason, the angle of incidence θ of the incident light on the BPF 32 needs to be limited, but if the angle of incidence θ is limited, the degree of freedom of optical design is reduced, and increasing a field of view of the lens group 31 and reducing height are hindered.

In addition, in order to store the BPF 32, it is necessary to dispose the BPF 32 so as to avoid contact with an individual imaging element 33, and this prevents height reduction of the solid-state imaging apparatus 11.

Therefore, in the present disclosure, any of the plurality of lenses 31a-1 to 31a-4 constituting the lens group 31 is provided further with a function equivalent to the BPF 32 in addition to a light condensing function, whereby the BPF 32 is omitted and the shift of a band of the incident light according to the angle of incidence of the incident light is reduced.

Thus, a distance between the lens group 31 and the solid-state imaging element 33 can be shortened, and downsizing and height reduction of the solid-state imaging apparatus 11 are achieved. In addition, since the BPF 32 is omitted, a limitation on the angle of incidence is eliminated and thus a wide angle of view can be achieved.

### 2. Preferred Embodiment

Next, with reference to FIG. 4, a configuration example of a solid-state imaging apparatus according to a preferred embodiment of the present disclosure will be described.

A solid-state imaging apparatus 111 in FIG. 4 includes a lens group 131, a solid-state imaging element 132, and a substrate 133. The solid-state imaging apparatus 111 in FIG. 4 has a configuration in which the lens group 131, the solid-state imaging element 132, and the substrate 133 are sequentially stacked in this order with respect to an incident direction of incident light from the top to the bottom in the figure.

Note that the solid-state imaging element 132 and the substrate 133 in FIG. 4 have configurations corresponding to those of the solid-state imaging element 33 and the substrate 34 in FIG. 1 and have the same functions, so that the description thereof will be omitted.

In other words, the solid-state imaging apparatus 111 in FIG. 4 is different from the solid-state imaging apparatus 11 in FIG. 1 in that the solid-state imaging apparatus 111 has a configuration in which a lens group 131 is provided instead of the lens group 31 and a BPF 32 is omitted.

As illustrated in FIG. 4, the lens group 131 has a configuration in which lenses 131a-1 to 131a-3 and 131b are stacked in a case 131x from the top in the figure. Here, the lenses 131a-1 to 131a-3 have configurations corresponding to the lenses 31a-1 to 31a-3 in FIG. 1 and have the same functions.

Basically, similarly to the lens 31a-4, the lens 131b is stacked with the lenses 131a-1 to 131a-3, whereby the lens 131b condenses the incident light on an imaging surface of the solid-state imaging element 132 similarly to the lens group 31.

However, the lens 131b not only condenses the incident light on the imaging surface of the solid-state imaging element 132 in cooperation with the lenses 131a-1 to 131a-3 but also further has a function corresponding to the BPF 32.

In other words, the lens 131b includes a material obtained by kneading a dye that absorbs a component of incident light in a predetermined visible light band at the BPF 32 into a transparent resin material.

For this reason, the lens 131b condenses the incident light on the imaging surface of the solid-state imaging element 132 in cooperation with the lenses 131a-1 to 131a-3 and absorbs a component of the incident light in a visible light band that is cut at the BPF 32 of the incident light and transmits near-infrared light, whereby the lens 131b functions substantially similarly to the BPF 32.

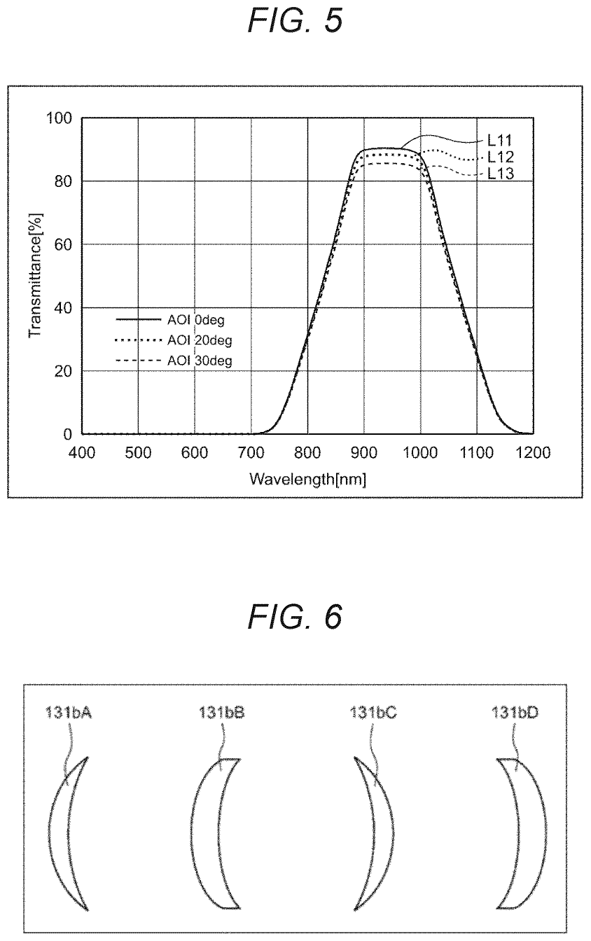

Since the lens 131b has a configuration in which a dye that absorbs a component in a visible and wide band that is cut by the BPF 32 is kneaded into a transparent resin material instead of a coating, there is no change in a band of transmitted light as illustrated in FIG. 5 even when an angle of incidence θ of the incident light changes.

Note that in FIG. 5, waveforms L11 to L13 illustrating transmittance distribution for each wavelength band of incident light having angles of incidence θ (AOI: angle of incidence) of 10 degrees, 20 degrees, and 30 degrees are illustrated.

In other words, as illustrated by the waveforms L11 to L13 in FIG. 5, it is illustrated that the lens 131b has no change in the transmittance distribution for each band even when the angle of incidence θ of the incident light changes to 10 degrees, 20 degrees, and 30 degrees.

With such a configuration, since the BPF 32 becomes unnecessary and a limitation on an angle of incidence of the incident light becomes unnecessary, the lens group 131 can be provided closer to the solid-state imaging element 132.

As a result, since the BPF 32 becomes unnecessary, a cost can be reduced, and downsizing, height reduction, and a wide angle of view of the solid-state imaging apparatus 111 can be achieved.

Note that hereinafter, the lens 131b in FIG. 4 is also particularly referred to as a dye lens 131b in order to distinguish the lens 131b from other lenses 131a.

### <Conditions for Dye Lens>

Next, conditions for the dye lens 131b in FIG. 4 will be described.

Note that here, the total number of the lenses 131a and the dye lens 131b constituting the lens group 131 is assumed to be any of 2 to 5, the effects of which have been empirically confirmed.

In addition, the dye lens 131b constituting the lens group 131 is desirably a so-called meniscus lens in which an incident surface and an emission surface have the same concave or convex shape in order to align an optical path of the incident light to some extent as a whole.

In other words, the dye lens 131b is desirably, for example, a meniscus lens as illustrated by the dye lenses 131bA to 131bD in FIG. 6.

Note that FIG. 6 illustrates an example of the cross-sectional shape of the meniscus lens that can be the dye lens 131b, and an incident direction of the incident light is a direction from right to left or a direction from left to right in the figure.

### (Thickness of Dye Lens)

The thickness of the dye lens 131b desirably satisfies the following conditional expressions (1) and (2).

$$0.1 mm < T < 1. 0 mm \qquad ( 1 )$$

$$T max / T min < 4. \qquad ( 2 )$$

Here, T represents the thickness in an optical axis direction within an effective diameter of the dye lens 131b.

In addition, Tmax is the maximum thickness in the optical axis direction within the effective diameter of the dye lens 131b, and Tmim is the minimum thickness in the optical axis direction within the effective diameter of the dye lens 131b.

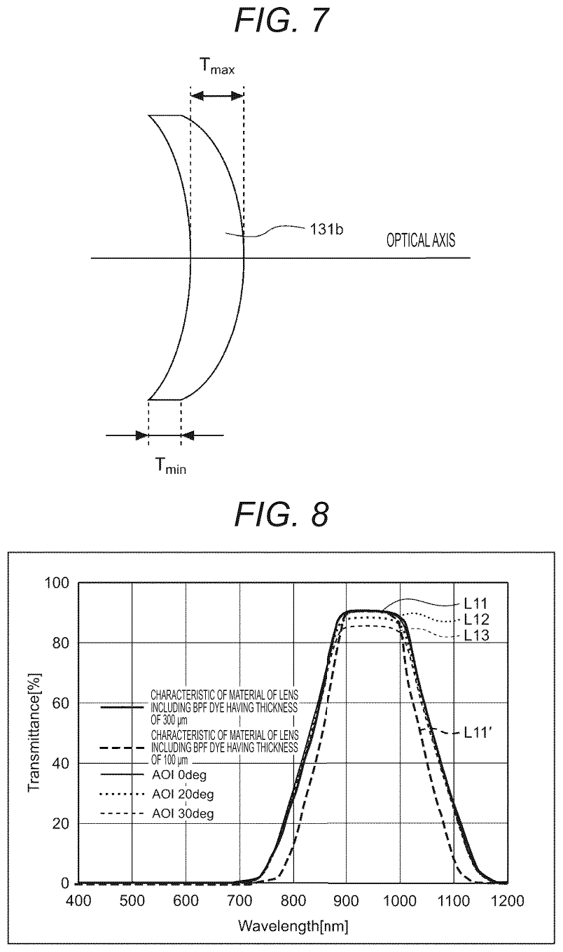

For example, in the case of a dye lens 131b having a shape as illustrated in FIG. 7, the thickness T at the center position in an optical axis direction within an effective diameter of the dye lens 131b becomes the maximum thickness Tmax, and the thickness T of the outermost edge portion becomes the minimum thickness Tmin.

If the thickness of the dye lens 131b changes as a whole, a transmittable wavelength band changes as illustrated in FIG. 8, so that light in a uniform wavelength band as a whole is not transmitted.

Note that in FIG. 8, a waveform L11 illustrated by a solid line represents a transmission characteristic at an angle of incidence of 0 degrees (AOI 0 deg) to a dye lens 131b including a BPF dye having a thickness of 300 μm, and a waveform L11′ illustrated by a dotted line represents a transmission characteristic at the angle of incidence of 0 degrees (AOI 0 deg) to a dye lens 131b including a BPF dye having a thickness of 100 μm.

Note that waveforms L12 and L13 are the same as those in FIG. 5.

As described above, since the dye lens 131b has a different transmission characteristic according to the thickness thereof, the thickness is locally different, and if a difference between the thicknesses increases, uniform light cannot be transmitted as a whole.

Therefore, the dye lens 131b desirably satisfies relationships in conditional expressions (1) and (2) described above, and transmits uniform light in a predetermined range as a whole.

More specifically, conditional expression (1) is a condition that defines the thickness of the dye lens 131b. If the thickness exceeds the upper limit, it becomes difficult to select a dye that cuts visible light, and if the thickness falls below the lower limit, it becomes difficult to mold and manufacture the dye lens.

In addition, conditional expression (2) is a condition that defines a thickness deviation ratio of a lens, and if the thickness deviation ratio exceeds the upper limit, a difference between the maximum thickness Tmax and the minimum thickness Tmin that are the thicknesses of the lens becomes large, it becomes difficult to keep lens transmittance constant, and it becomes difficult to perform molding and manufacturing.

### (Optical Path Length of Dye Lens)

Moreover, the dye lens 131b desirably satisfies relationships in the following conditional expressions (3) and (4).

$$\vert Vc - Vp \vert / n < 0.2 mm \qquad ( 3 )$$

$$( Vi\_max - Vi\_min ) / n < 0.2 mm \qquad ( 4 )$$

Here, Vc represents an optical path length of a main light ray at an image height center, Vp represents an optical path length of the main light ray at an image height of 80%, and n represents a refractive index at a main wavelength.

Here, Vi_max represents the maximum optical path length at an image height i, Vi_min represents the minimum optical path length at the image height i, and i represents 0 to 80% of the image height.

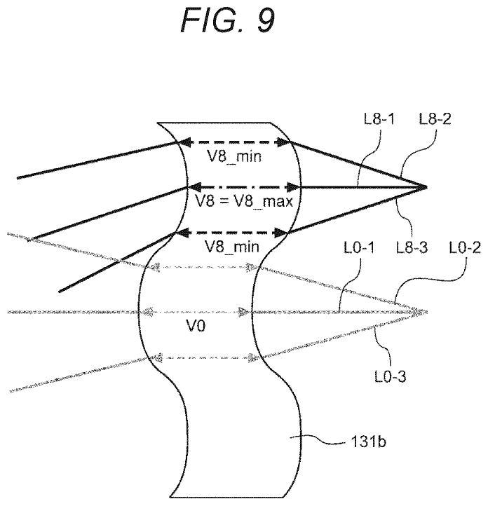

For example, in a case where, for a dye lens 131b having a shape as illustrated in FIG. 9, an optical path L0-1 at an image height center and optical paths L0-2 and L0-3 at a peripheral image height of the dye lens 131b are present, and an optical path L8-1 at an image height of 80% and optical paths L8-2 and L8-3 at a peripheral image height of the dye lens 131b are present, the left side of each of conditional expressions (3) and (4) is expressed as follows.

In other words, the left side of conditional expression (3) is | V0−V8|/n, and in the case of i=80%, the left side of conditional expression (4) is (V8_max−V8_min)/n.

In the case of FIG. 9, if each of |V0−V8|/n and (V8_max−V8_min)/n (i=80%) is less than 0.2 mm, conditional expression (3) and conditional expression (4) are satisfied. Note that, although FIG. 9 illustrates an example in the case of i=80%, as for conditional expression (4), it is necessary that i satisfies a condition for all of 0 to 80%.

In other words, conditional expression (3) is a condition that defines a difference between a lens transmission optical path of a main light ray at an image height center and a lens transmission optical path of the main light ray at a peripheral image height. In a case where the condition of conditional expression (3) is satisfied, the transmittance of the dye lens 131b can be kept constant regardless of an image height position, and it is possible to reduce deterioration of a peripheral light amount ratio caused by a difference between a lens transmission optical path of a main light ray at an image height center of the dye lens 131b and a lens transmission optical path of the main light ray at the peripheral image height thereof.

In addition, conditional expression (4) is a condition that defines a difference between a lens transmission optical path of the main light ray and a lens transmission optical path of a peripheral light beam at each image height, and when the condition of the conditional expression (4) is satisfied, the transmittance of the main light ray and the peripheral light beam can be kept constant, and a decrease in a light amount at each image height can be reduced.

The dye lens 131b is set so that the dye lens 131b satisfies the conditions of conditional expressions (1) to (4) described above, whereby the dye lens 131b as a whole can condense the incident light on the imaging surface of the solid-state imaging element 132 with a certain uniform light amount and achieve the function of the BPF 32.

Thus, since the BPF 32 becomes unnecessary, downsizing and height reduction of an apparatus configuration can be achieved, and a manufacturing process and a manufacturing cost can be reduced by omitting the BPF 32. In addition, since a change of the transmission characteristic according to an angle of incidence of the incident light is also reduced, a wide angle of view can also be achieved.

Note that in the above description, an example in which one in the lens group 131 is set as the dye lens 131b has been described. However, although a plurality of dye lenses 131b may be provided as long as the above conditions are satisfied, it is desirable to set the number of dye lenses 131b to one in order to reduce a cost.

In addition, in a case where conditional expressions (1) to (4) are satisfied for a plurality of lenses 131a, the lens 131a that is optimal among the plurality of lenses 131a may be set as the dye lens 131b.

Here, the lens 131a that is optimal among the plurality of lenses 131a in a case where the conditional expressions (1) to (4) are satisfied is, for example, the lens 131a such that all or at least one of a ratio Tmax/Tmin in conditional expression (2), a value (|Vc−Vp|/n) on the left side of conditional expression (3), and a value ((Vi_max−Vi_min)/n) on the left side of conditional expression (4) are the smallest, or the plurality of lenses 131a that is ranked high in a case where the plurality of lenses 131a is ranked in ascending order.

Furthermore, in a case where conditional expressions (1) to (4) are satisfied for the plurality of lenses 131a, if there is a priority, for example, giving priority to the height of the transmission characteristic, giving priority to cost reduction, or the like, any of the plurality of lenses 131a may be selected according to the priority and set as the dye lens 131b.

<Example in which Lens Group Includes Two Lenses>

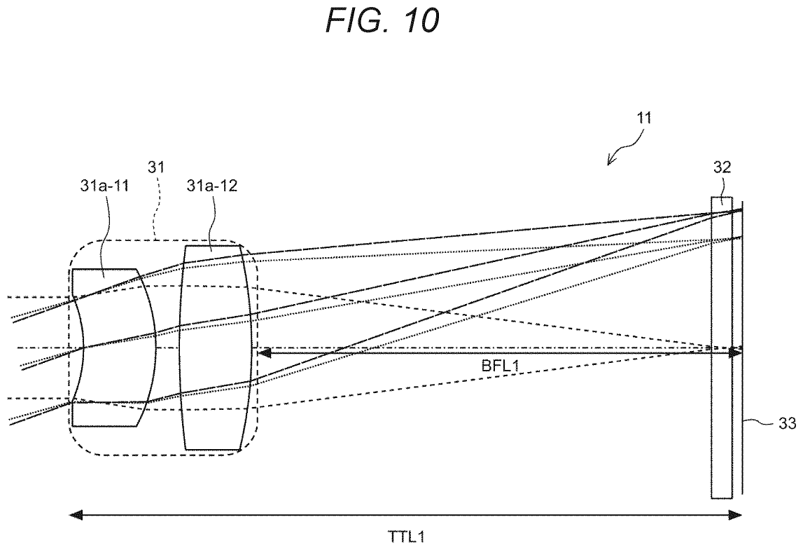

Next, with reference to FIGS. 10 to 13, a method of determining, in a case where a lens group 131 includes two lenses 131a, which of the lenses 131a is to be set as a dye lens 131b, and a specific example of an effect generated by omitting a BPF 32 will be described.

FIG. 10 illustrates a configuration example of a solid-state imaging apparatus 11 with a BPF and including a lens group 31 including two lenses 31a-11 and 31a-12, a BPF 32, and a solid-state imaging element 33.

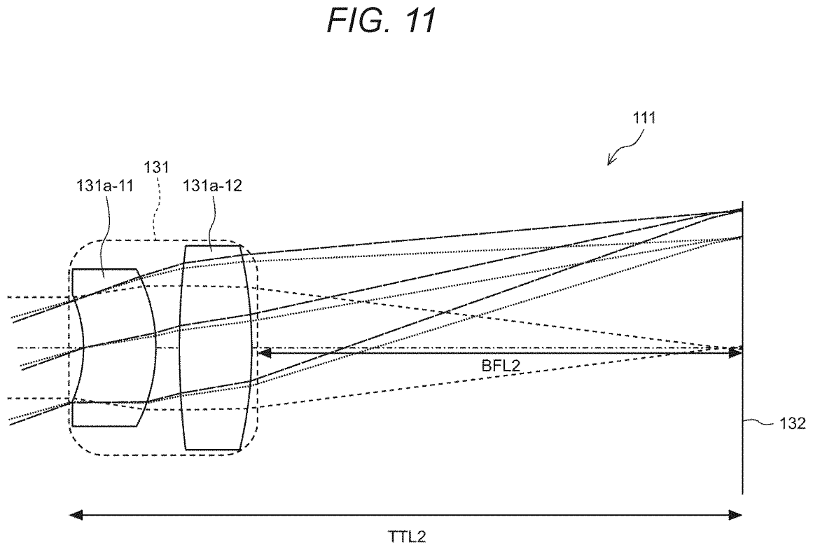

In addition, FIG. 11 illustrates a configuration example of a solid-state imaging apparatus 111 without a BPF and including a lens group 131 including two lenses 131a-11 and 131a-12 and a solid-state imaging element 132.

Note that in the figures, a solid line, a dotted line, or the like in the lens groups 31 and 131 illustrates a part of an optical path of light incident from the left to the right in the figures and represents that the solid-state imaging apparatuses 11 and 111 in FIGS. 10 and 11 forms images of the incident light on the imaging surfaces of the solid-state imaging elements 32 and 132.

In other words, both the lens groups 31 and 131 in FIGS. 10 and 11 form the same image from the same incident light on the imaging surfaces of the solid-state imaging elements 33 and 132.

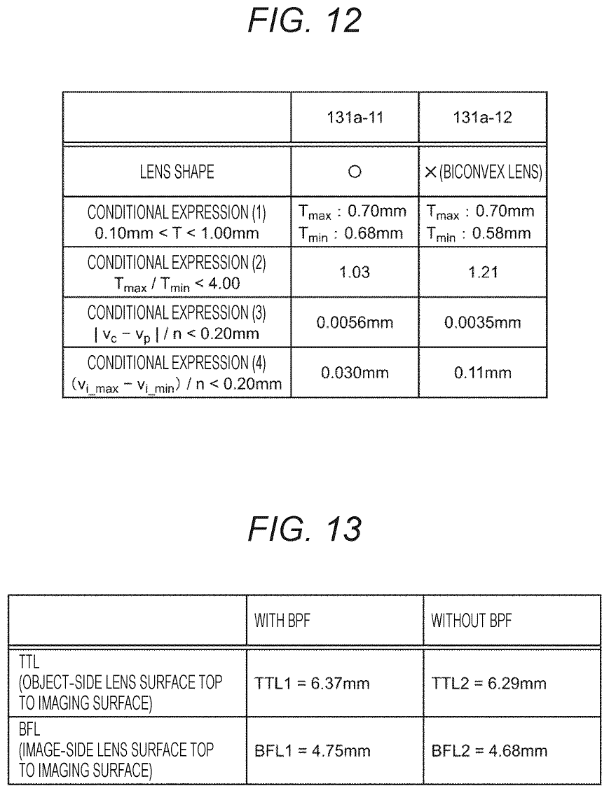

Here, a case where the lenses 131a-11 and 131a-12 constituting the lens group 131 has characteristics as illustrated in FIG. 12 will be considered.

Note that in FIG. 12, a specific example of each of a “lens shape” and “conditional expression (1)” to “conditional expression (4)” is illustrated from the uppermost row for each of the lenses 131a-11 and 131a-12 from the left in the figure.

In other words, in FIG. 12, the lens shape of the lens 131a-11 is a meniscus lens, as illustrated in FIG. 11, and satisfies a condition for the lens shape. However, the lens 131a-12 is a biconvex lens, as illustrated in FIG. 11 and does not satisfy the condition for the lens shape.

In addition, as for conditional expression (1), the maximum thickness Tmax and the minimum thickness Tmin of the lens 131a-11 are 0.70 mm and 0.68 mm, respectively, and the maximum thickness Tmax and the minimum thickness Tmin of the lens 131a-12 are 0.70 mm and 0.58 mm, respectively. In other words, since the thickness T of each of the lenses 131a-11 and 131a-12 are larger than 0.1 mm and smaller than 1 mm, conditional expression (1) is satisfied.

Moreover, as for conditional expression (2), Tmax/Tmin of the lens 131a-11 is 1.03, and Tmax/Tmin of the lens 131a-2 is 1.21. In other words, since Tmax/Tmin of each of the lenses 131a-11 and 131a-12 is less than 4.00, conditional expression (2) is satisfied.

In addition, as for conditional expression (3), |Vc−Vp|/n of the lens 131a-11 is 0.0056 mm, and |Vc−Vp|/n of the lens 131a-12 is 0.0035 mm. In other words, |Vc−Vp|/n of each of the lenses 131a-11 and 131a-12 is smaller than 0.20 mm, and conditional expression (3) is satisfied.

Moreover, as for conditional expression (4), (Vi_max-Vi_min)/n of the lens 131a-11 is 0.030 mm, and (Vi_max-Vi_min)/n of the lens 131a-12 is 0.11 mm. In other words, (Vi_max−Vi_min)/n of each of the lenses 131a-11 and 131a-12 is smaller than 0.20 mm and conditional expression (4) is satisfied.

Since the lens 131a-11 satisfies the lens shape and all of conditional expressions (1) to (4) on the basis of the above characteristics, the lens 131a-11 of the lenses 131a-11 and 131a-12 is set as a dye lens 131b in the lens group 131 illustrated in FIG. 11. In other words, in the solid-state imaging apparatus 111 of FIG. 11, instead of the lens 131a-11, there is set the dye lens 131b that has the same shape as a shape of the lens 131a-11 and includes a resin material kneaded with a dye that absorbs visible light and transmits near-infrared light.

Thus, as illustrated in FIG. 13, in the solid-state imaging apparatus 11 with the BPF in FIG. 10, a distance total track length (TTL) from an object-side lens surface top of the lens group 31 to the imaging surface of the solid-state imaging element 33 is TTL1=6.37 mm, whereas in the solid-state imaging apparatus 111 without the BPF in FIG. 11, a distance TTL from the object-side lens surface top of the lens group 131 to the imaging surface of the solid-state imaging element 132 is TTL2=6.29 mm.

In addition, as illustrated in FIG. 13, in the solid-state imaging apparatus 11 with the BPF in FIG. 10, a distance back forcal length (BFL) from the image surface-side lens surface top of the lens group 31 to the imaging surface of the solid-state imaging element 33 is BFL1=4.75 mm, whereas in the solid-state imaging apparatus 111 without the BPF in FIG. 11, a distance BFL from the image surface-side lens surface top of the lens group 131 to the imaging surface of the solid-state imaging element 132 is BFL2=4.68 mm.

In other words, both of the distances TTL and BFL in the solid-state imaging apparatus 111 without the BPF in FIG. 11 are smaller than those in the solid-state imaging apparatus 11 with the BPF in FIG. 10, and it is clear that downsizing and height reduction of an apparatus configuration are achieved by the solid-state imaging apparatus 111 of the present disclosure.

In addition, since the dye lens 131b has a configuration in which a dye that absorbs visible light in a predetermined frequency band is kneaded into a transparent resin material, a wavelength band of transmitted light does not shift according to an angle of incidence as illustrated in FIG. 5 and thus a wide angle of view can be achieved.

### <Example in Which Lens Group Includes Three Lenses>

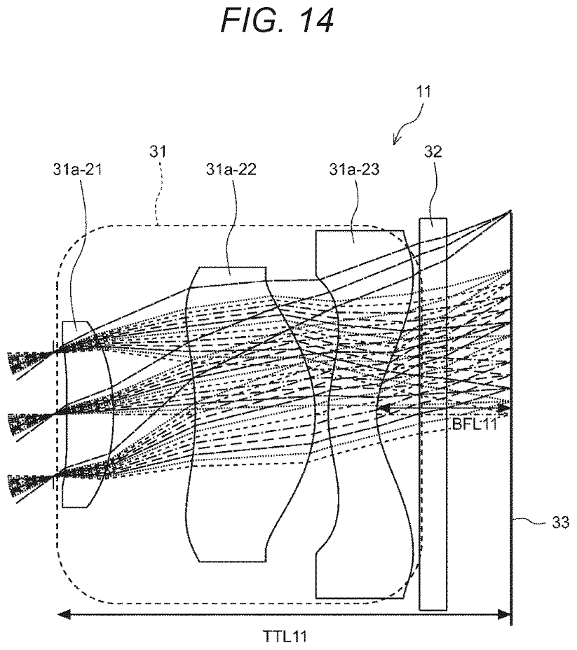

Next, with reference to FIGS. 14 to 17, a method of determining, in a case where a lens group 131 includes three lenses 131a, which of the lenses 131a is to be set as a dye lens 131b, and a specific example of an effect generated by omitting a BPF 32 will be described.

FIG. 14 illustrates a configuration example of a solid-state imaging apparatus 11 with a BPF and including a lens group 31 including three lenses 31a-21 to 31a-23, a BPF 32, and a solid-state imaging element 33.

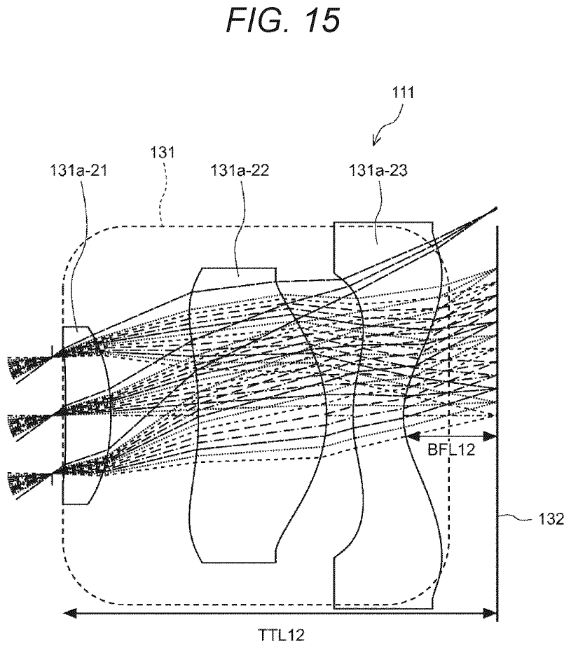

In addition, FIG. 15 illustrates a configuration example of a solid-state imaging apparatus 111 without a BPF and including a lens group 131 including three lenses 131a-21 to 131a-23 and a solid-state imaging element 132.

Note that in the figures, a solid line, a dotted line, or the like in the lens group 31 and 131 illustrates a part of an optical path of light incident from the left to the right in the figures and represents that the solid-state imaging apparatus 11 and 111 in FIGS. 14 and 15 forms images of the incident light on the imaging surfaces of the solid-state imaging elements 32 and 132.

In other words, both the lens groups 31 and 131 in FIGS. 14 and 15 form the same image from the same incident light on the imaging surface of the solid-state imaging element 33 and 132.

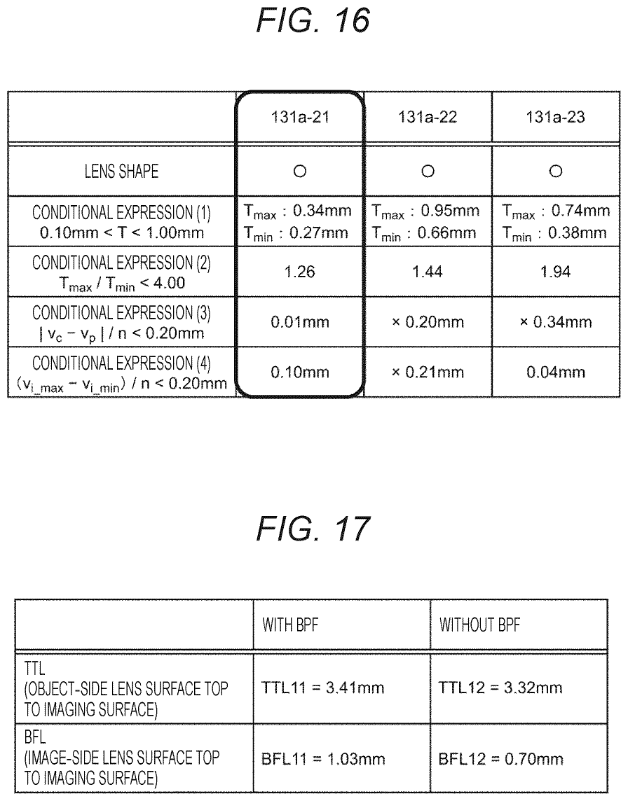

Here, a case where the lenses 131a-21 to 131a-23 constituting the lens group 131 have characteristics as illustrated in FIG. 16 will be considered.

Note that in FIG. 16, a specific example of each of a “lens shape” and the “conditional expression (1)” to “conditional expression (4)” is illustrated from the uppermost row for each of the lenses 131a-21 to 131a-23 from the left in the figure.

In other words, all of the lenses 131a-21 to 131a-23 in FIG. 16 have a lens shape of a meniscus lens, as illustrated in FIG. 15 and satisfy the condition for the lens shape.

In addition, as for conditional expression (1), the maximum thickness Imax and the minimum thickness Imin of the lens 131a-21 are 0.34 mm and 0.27 mm, respectively, the maximum thickness Tmax and the minimum thickness Tmin of the lens 131a-22 are 0.95 mm and 0.66 mm, respectively, and the maximum thickness Tmax and the minimum thickness Tmin of the lens 131a-23 are 0.74 mm and 0.38 mm, respectively. In other words, since the thickness T of each of the lenses 131a-21 to 131a-23 is larger than 0.1 mm and smaller than 1 mm, conditional expression (1) is satisfied.

Moreover, as for conditional expression (2), Tmax/Imin of the lens 131a-21 is 1.26, Tmax/Tmin of the lens 131a-22 is 1.44, and Tmax/Imin of the lens 131a-23 is 1.94. In other words, since Tmax/Tmin of each of the lenses 131a-21 to 131a-23 is less than 4.00, conditional expression (2) is satisfied.

In addition, as for conditional expression (3), |Vc−Vp|/n of the lens 131a-21 is 0.01 mm, |Vc−Vp|/n of the lens 131a-22 is 0.20 mm, and the lens 131a-23 is 0.34 mm. In other words, |Vc
Vp|/n of the lens 131a-21 is smaller than 0.20 mm and satisfies conditional expression (3), but |Vc−Vp|/n of the lens 131a-22 and 131a-23 does not satisfy conditional expression (3).

Moreover, as for conditional expression (4), (Vi_max-Vi_min)/n of the lens 131a-21 is 0.10 mm, (Vi_max−Vi_min)/n of the lens 131a-22 is 0.21 mm, and (Vi_max−Vi_min)/n of the lens 131a-23 is 0.04 mm. In other words, (Vi_max−Vi_min)/n of the lens 131a-21 and 131a-23 is smaller than 0.20 mm and satisfies conditional expression (4), but (Vi_max−Vi_min)/n of the lens 131a-22 is larger than 0.20 mm and does not satisfy conditional expression (4).

Since the lens 131a-21 satisfies all of conditional expressions (1) to (4) on the basis of the above characteristics, the lens 131a-21 of the lenses 131a-21 to 131a-23 and a dye lens 131b are set in the lens group 131 illustrated in FIG. 15. In other words, in the solid-state imaging apparatus 111 of FIG. 15, instead of the lens 131a-21, there is set the dye lens 131b that has the same shape as a shape of the lens 131a-21 and includes a resin material kneaded with a dye that absorbs visible light and transmits near-infrared light.

Thus, as illustrated in FIG. 17, in the solid-state imaging apparatus 11 with the BPF in FIG. 14, a distance total track length (TTL) from an object-side lens surface top of the lens group 31 to the imaging surface of the solid-state imaging element 33 is TTL11=3.41 mm, whereas in the solid-state imaging apparatus 111 without the BPF in FIG. 15, a distance TTL from an object-side lens surface top of the lens group 131 to the imaging surface of the solid-state imaging element 132 is TTL12=3.32 mm.

In addition, as illustrated in FIG. 17, in the solid-state imaging apparatus 11 with the BPF in FIG. 14, a distance back forcal length (BFL) from the image surface-side lens surface top of the lens group 31 to the imaging surface of the solid-state imaging element 33 is BFL11=1.03 mm, whereas in the solid-state imaging apparatus 111 without the BPF in FIG. 15, the distance BFL from the image surface-side lens surface top of the lens group 131 to the imaging surface of the solid-state imaging element 132 is BFL12=0.70 mm.

That is, both of the distances TTL and BFL in the solid-state imaging apparatus 111 without the BPF in FIG. 15 are smaller than those in the solid-state imaging apparatus 11 with the BPF in FIG. 14, and it is clear that downsizing and height reduction of an apparatus configuration are achieved by the solid-state imaging apparatus 111 of the present disclosure.

In addition, since the dye lens 131b has a configuration in which a dye that absorbs visible light in a predetermined frequency band is kneaded into a transparent resin material, a wavelength band of transmitted light does not shift according to an angle of incidence as illustrated in FIG. 5 and thus a wide angle of view can be achieved.

### <Example in Which Lens Group Includes Four Lenses>

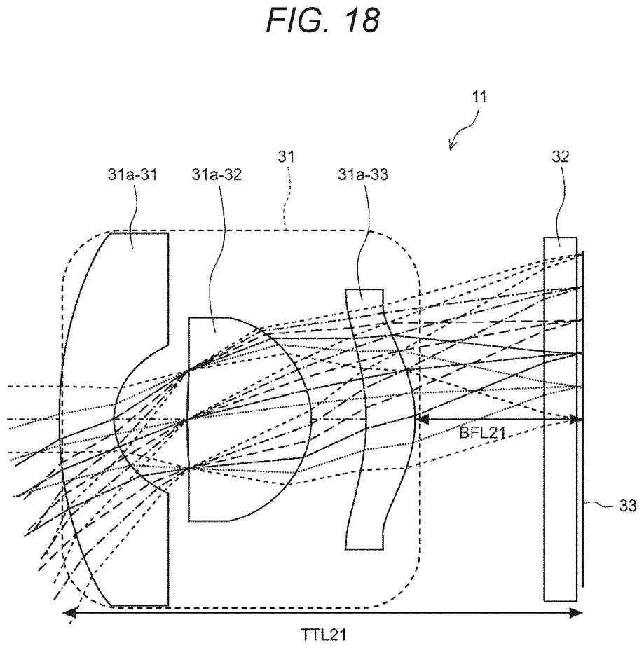

Next, with reference to FIGS. 18 to 21, a method of determining, in a case where a lens group 131 includes four lenses 131a, which of the lenses 131a is to be set as a dye lens 131b, and a specific example of an effect generated by omitting a BPF 32 will be described.

FIG. 18 illustrates a configuration example of a solid-state imaging apparatus 11 with a BPF and including a lens group 31 including three lenses 31a-31 to 31a-33, a BPF 32, and a solid-state imaging element 33.

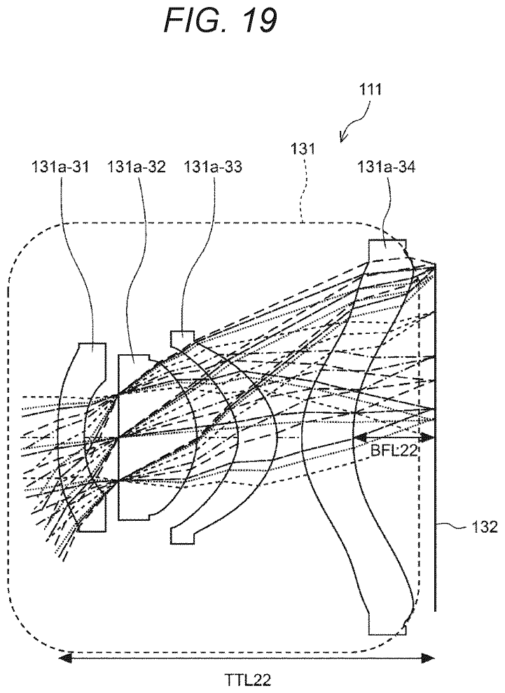

In addition, FIG. 19 illustrates a configuration example of a solid-state imaging apparatus 111 without a BPF and including a lens group 131 including four lenses 131a-31 to 131a-34 and a solid-state imaging element 132.

Note that in the figures, a solid line, a dotted line, or the like in the lens group 31 and 131 illustrates an optical path of light incident from the left to the right in the figures and represents that the solid-state imaging apparatus 11 and 111 in FIGS. 18 and 19 forms images on the imaging surfaces of the solid-state imaging element 33 and 132.

In other words, both the lens groups 31 and 131 in FIGS. 18 and 19 form substantially the same image from the same incident light on the imaging surfaces of the solid-state imaging element 33 and 132.

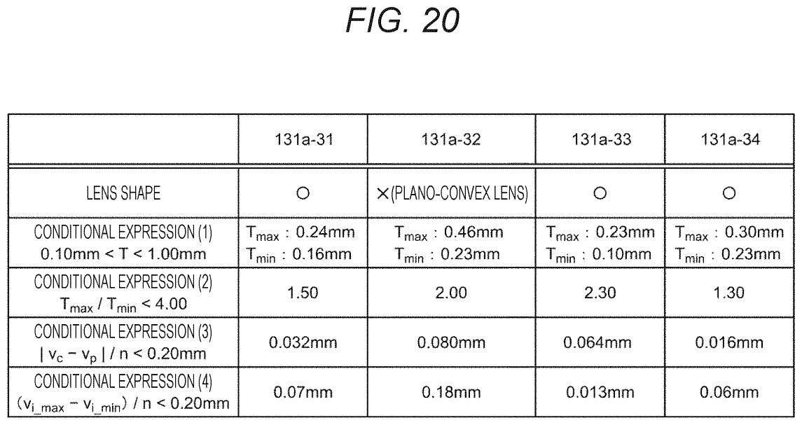

Here, a case where the lenses 131a-31 to 131a-34 constituting the lens group 131 have characteristics as illustrated in FIG. 20 will be considered.

Note that in FIG. 20, a specific example of each of a “lens shape” and “conditional expression (1)” to “conditional expression (4)” is illustrated from the uppermost row for each of the lenses 131a-31 to 131a-34 from the left in the figure.

In other words, all of the lenses 131a-31, 131a-33, and 131a-34 in FIG. 20 have a lens shape of a meniscus lens, as illustrated in FIG. 18 and therefore satisfy the condition for the lens shape. However, since the lens 131a-32 is a plano-convex lens, the lens 131a-32 is not a meniscus lens and therefore do not satisfy the condition.

In addition, as for conditional expression (1), the maximum thickness Tmax and the minimum thickness Imin of the lens 131a-31 are 0.24 mm and 0.16 mm, respectively, the maximum thickness Tmax and the minimum thickness Imin of the lens 131a-32 are 0.46 mm and 0.23 mm, respectively, the maximum thickness Tmax and the minimum thickness Tmin of the lens 131a-33 are 0.23 mm and 0.10 mm, respectively, and the maximum thickness Tmax and the minimum thickness Tmin of the lens 131a-34 are 0.30 mm and 0.23 mm, respectively. In other words, since the thickness I of any of the lenses 131a-31 to 131a-34 is larger than 0.1 mm and smaller than 1 mm, conditional expression (1) is satisfied.

Moreover, as for conditional expression (2), Tmax/Tmin of the lens 131a-31 is 1.50, Tmax/Imin of the lens 131a-32 is 2.00, Imax/Tmin of the lens 131a-33 is 2.30, and Tmax/Tmin of the lens 131a-34 is 1.30. In other words, since Imax/Imin of any of the lenses 131a-31 to 131a-34 is less than 4.00, conditional expression (2) is satisfied.

In addition, as for conditional expression (3), |Vc−Vp|/n of the lens 131a-31 is 0.032 mm, |Vc−Vp|/n of the lens 131a-32 is 0.080 mm, |Vc−Vp|/n of the lens 131a-33 is 0.064 mm, and |Vc−Vp|/n of the lens 131a-34 is 0.016 mm. In other words, |Vc −Vp|/n of any of the lenses 131a-31 to 131a-34 satisfies conditional expression (3).

Moreover, as for conditional expression (4), (Vi_max−Vi_min)/n of the lens 131a-31 is 0.07 mm, (Vi_max−Vi_min)/n of the lens 131a-32 is 0.18 mm, (Vi_max−Vi_min)/n of the lens 131a-33 is 0.013 mm, and (Vi_max−Vi_min)/n of the lens 131a-34 is 0.06 mm. In other words, (Vi_max−Vi_min)/n of any of the lenses 131a-31 to 131a-34 satisfies conditional expression (4).

Since the lens 131a-31, 131a-33, and 131a-34 satisfies all of conditional expressions (1) to (4) on the basis of the above characteristics, at least one of the lenses 131a-31 to 131a-34 among the lenses 131a-31, 131a-33, and 131a-34 is set as a dye lens 131b in the lens group 131 illustrated in FIG. 19.

In the case of FIG. 20, in any of conditional expressions (1) to (4), as a value is away from a threshold value, an excellent characteristic can be obtained. Therefore, in a case where the superiority of an optical characteristic is emphasized, it is desirable to set the lens 131a-34 as the dye lens 131b.

Note that since the lens 131a-34 is closest to the solid-state imaging element 132, it can be said that it is desirable to set the lens 131a-34 as the dye lens 131b even in consideration of stray light.

In addition, since a cost can be reduced as an amount of a dye to be kneaded is reduced, in a case where the cost is emphasized, it is desirable to set the lens 131a-31 having the smallest volume as the dye lens 131b.

As described above, the lens 131a set as the dye lens 131b corresponds to a purpose. may be selected.

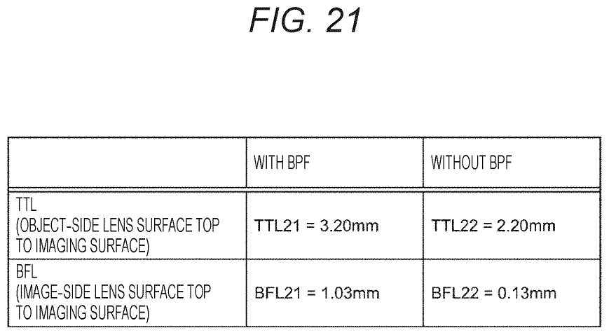

With such a configuration, as illustrated in FIG. 21, in the solid-state imaging apparatus 11 with the BPF in FIG. 18, a distance total track length (TTL) from the object-side lens surface top of the lens group 31 to an imaging surface of a solid-state imaging element 33 is TTL21=3.20 mm, whereas in the solid-state imaging apparatus 111 without the BPF in FIG. 19, a distance TTL from an object-side lens surface top of the lens group 131 to the imaging surface of the solid-state imaging element 132 is TTL22=2.20 mm.

In addition, as illustrated in FIG. 21, in the solid-state imaging apparatus 11 with the BPF in FIG. 18, a distance back forcal length (BFL) from the image surface-side lens surface top of the lens group 31 to the imaging surface of the solid-state imaging element 33 is BFL21=1.03 mm, whereas in the solid-state imaging apparatus 111 without the BPF in FIG. 19, a distance BFL from the image surface-side lens surface top of the lens group 131 to the imaging surface of the solid-state imaging element 132 is BFL22=0.13 mm.

In other words, both of the distances TIL and BFL in the solid-state imaging apparatus 111 without the BPF in FIG. 19 are smaller than those in the solid-state imaging apparatus 11 with the BPF in FIG. 18, and it is clear that downsizing and height reduction of an apparatus configuration are achieved by the solid-state imaging apparatus 111 of the present disclosure.

In addition, since the dye lens 131b has a configuration in which a dye that absorbs visible light in a predetermined frequency band and transmits near-infrared light is kneaded into a transparent resin material, a wavelength band of transmitted light does not shift according to an angle of incidence as illustrated in FIG. 5 and thus a wide angle of view can be achieved.

<Example in which Lens Group Includes Five Lenses>

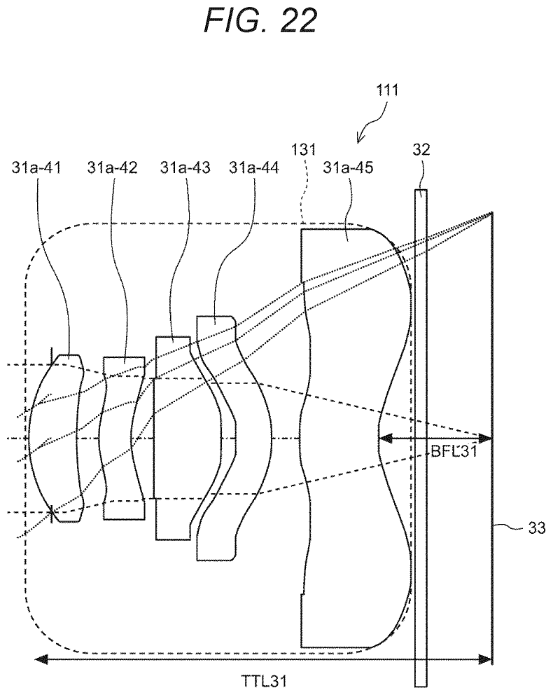

Next, with reference to FIGS. 22 to 25, a method of determining, in a case where a lens group 131 includes five lenses 131a, which of the lenses 131a is to be set as a dye lens 131b, and a specific example of an effect generated by omitting a BPF 32 will be described.

FIG. 22 illustrates a configuration example of a solid-state imaging apparatus 11 with a BPF and including a lens group 31 including five lenses 31a-41 to 31a-45, a BPF 32, and a solid-state imaging element 33.

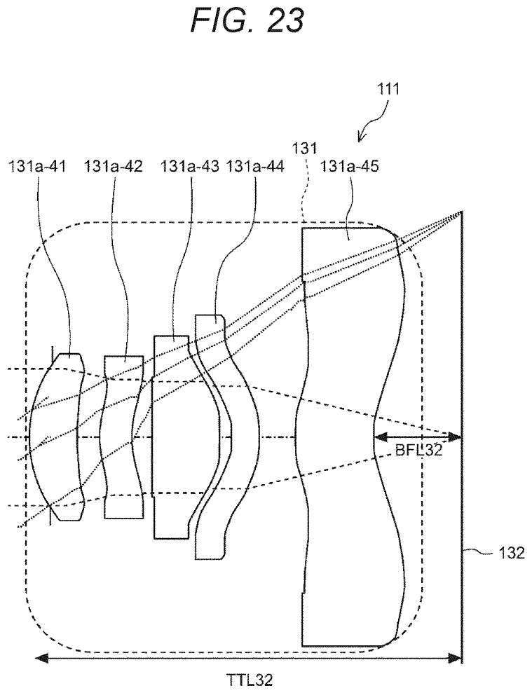

In addition, FIG. 23 illustrates a configuration example of a solid-state imaging apparatus 111 without a BPF and including a lens group 131 including five lenses 131a-41 to 131a-45 and a solid-state imaging element 132.

Note that in the figures, a solid line, a dotted line, or the like in the lens group 31 and 131 illustrates an optical path of light incident from the left to the right in the figures and represents that the solid-state imaging apparatus 11 and 111 in FIGS. 22 and 23 forms images on the imaging surfaces of the solid-state imaging element 33 and 132.

In other words, both the lens groups 31 and 131 in FIGS. 22 and 23 form substantially the same image from the same incident light on the imaging surfaces of the solid-state imaging elements 33 and 132.

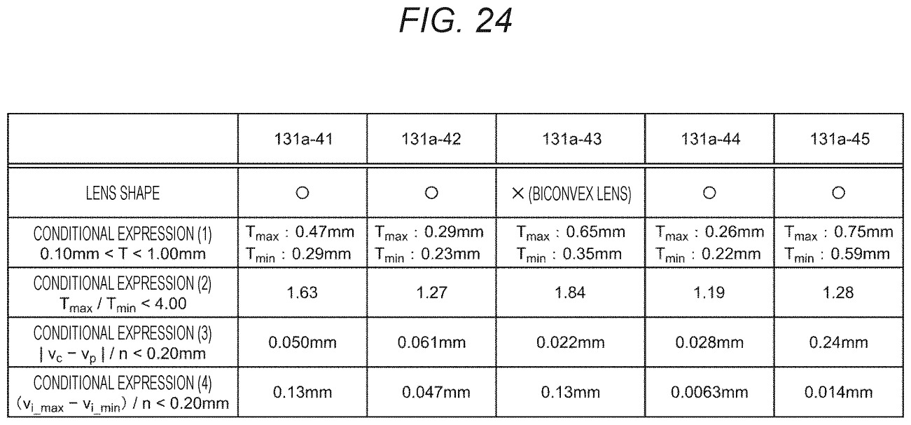

Here, a case where the lenses 131a-41 to 131a-45 constituting the lens group 131 have characteristics as illustrated in FIG. 24 will be considered.

Note that in FIG. 24, a specific example of each of a “lens shape” and “conditional expression (1)” to “conditional expression (4)” is illustrated from the uppermost row for each of the lenses 131a-41 to 131a-45 from the left in the figure.

In other words, all of the lenses 131a-41, 131a-42, 131a-44, and 131a-45 in FIG. 24 have a lens shape of a meniscus lens, as illustrated in FIG. 22 and therefore satisfy the condition for the lens shape. However, since the lens 131a-43 is a biconvex lens, the lens 131a-43 is not a meniscus lens and therefore does not satisfy the condition.

In addition, as for conditional expression (1), the maximum thickness Tmax and the minimum thickness Tmin of the lens 131a-41 are 0.47 mm and 0.29 mm, respectively, the maximum thickness Tmax and the minimum thickness Imin of the lens 131a-42 are 0.29 mm and 0.23 mm, respectively, the maximum thickness Tmax and the minimum thickness Tmin of the lens 131a-43 are 0.65 mm and 0.35 mm, respectively, the maximum thickness Tmax and the minimum thickness Imin of the lens 131a-44 are 0.26 mm and 0.22 mm, respectively, and the maximum thickness Tmax and the minimum thickness Tmin of the lens 131a-45 are 0.75 mm and 0.59 mm, respectively. In other words, since the thickness T of any of the lenses 131a-41 to 131a-45 is larger than 0.1 mm and smaller than 1 mm, conditional expression (1) is satisfied.

Moreover, as for conditional expression (2), Tmax/Imin of the lens 131a-41 is 1.63, Tmax/Tmin of the lens 131a-42 is 1.27, Tmax/Imin of the lens 131a-43 is 1.84, Tmax/Tmin of the lens 131a-44 is 1.19, and Tmax/Tmin of the lens 131a-45 is 1.28. In other words, since Tmax/Imin of any of the lenses 131a-41 to 131a-45 is less than 4.00, conditional expression (2) is satisfied.

In addition, as for the conditional expression (3), |Vc-Vp|/n of the lens 131a-41 is 0.050 mm, |Vc−Vp|/n of the lens 131a-42 is 0.061 mm, |Vc−Vp|/n of the lens 131a-43 is 0.022 mm, |Vc−Vp|/n of the lens 131a-44 is 0.028 mm, and |Vc−Vp|/n of the lens 131a-45 is 0.24 mm. In other words, |Vc−Vp|/n of the lenses 131a-41 to 131a-44 satisfies conditional expression (3), but |Vc−Vp|/n of the lens 131a-45 does not satisfy conditional expression (3).

Moreover, as for conditional expression (4), (Vi_max-Vi_min)/n of the lens 131a-41 is 0.13 mm, (Vi_max−Vi_min)/n of the lens 131a-42 is 0.047 mm, (Vi_max−Vi_min)/n of the lens 131a-43 is 0.13 mm, (Vi_max−Vi_min)/n of the lens 131a-44 is 0.0063 mm, and (Vi_max−Vi_min)/n of the lens 131a-45 is 0.014 mm. In other words, (Vi_max−Vi_min)/n of any of the lenses 131a-41 to 131a-45 satisfies conditional expression (4).

Since the lens 131a-41, 131a-42, and 131a-44 satisfies all of conditional expressions (1) to (4) on the basis of the above characteristics, at least one of the lenses 131a-41 to 131a-45 among the lenses 131a-41, 131a-42, and 131a-44 is set as a dye lens 131b in the lens group 131 illustrated in FIG. 23.

In the case of FIG. 24, in any of the conditional expressions (1) to (4), as a value is away from a threshold value, an excellent characteristic can be obtained. Therefore, in a case where the superiority of an optical characteristic is emphasized, it is desirable to set the lens 131a-44 as the dye lens 131b.

Note that since the lens 131a-44 among the lenses 131a that can be set as the dye lens 131b is close to the solid-state imaging element 132, it can be said that it is desirable to set the lens as the dye lens 131b even in consideration of stray light.

In addition, since a cost can be reduced as an amount of a dye to be kneaded is reduced, in a case where the cost is emphasized, it is desirable to set the lens 131a-42 having the smallest volume as the dye lens 131b.

As described above, the lens 131a set as the dye lens 131b corresponds to a purpose. may be selected.

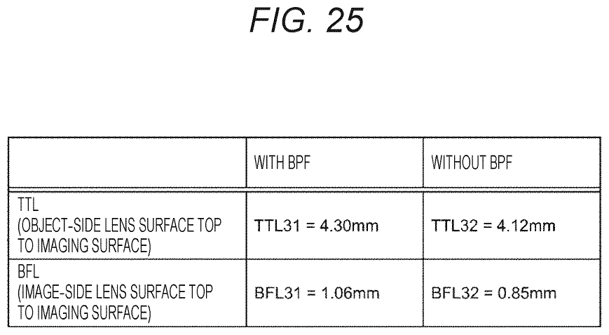

With such a configuration, as illustrated in FIG. 25, in the solid-state imaging apparatus 11 with the BPF in FIG. 22, a distance total track length (TTL) from the object-side lens surface top of the lens group 31 to the imaging surface of the solid-state imaging element 33 is TTL31=4.30 mm, whereas in the solid-state imaging apparatus 111 without the BPF in FIG. 23, a distance TTL from an object-side lens surface top of the lens group 131 to the imaging surface of the solid-state imaging element 132 is TIL32=4.12 mm.

In addition, as illustrated in FIG. 25, in the solid-state imaging apparatus 11 with the BPF in FIG. 22, a distance back forcal length (BFL) from the image surface-side lens surface top of the lens group 31 to the imaging surface of the solid-state imaging element 33 is BFL31=1.06 mm, whereas in the solid-state imaging apparatus 111 without the BPF in FIG. 23, a distance BFL from the image surface-side lens surface top of the lens group 131 to the imaging surface of the solid-state imaging element 132 is BFL32=0.85 mm.

In other words, both of the distances TTL and BFL in the solid-state imaging apparatus 111 without the BPF in FIG. 23 are smaller than those in the solid-state imaging apparatus 11 with the BPF in FIG. 22, and it is clear that downsizing and height reduction of an apparatus configuration are achieved by the solid-state imaging apparatus 111 of the present disclosure.

In addition, since the dye lens 131b has a configuration in which a dye that absorbs visible light in a predetermined frequency band and transmits near-infrared light is kneaded into a transparent resin material, a wavelength band of transmitted light does not shift according to an angle of incidence as illustrated in FIG. 5 and thus a wide angle of view can be achieved.

### 3. Modification Examples

In the above description, there have been described examples in which the dye lens 131b includes a transparent resin material into which a dye that absorbs a component of incident light in a visible light band to be cut in the BPF 32 and transmits near infrared light is kneaded, but a coating that cuts visible light and transmits near infrared light may be applied to the surface of any lens of a lens group.

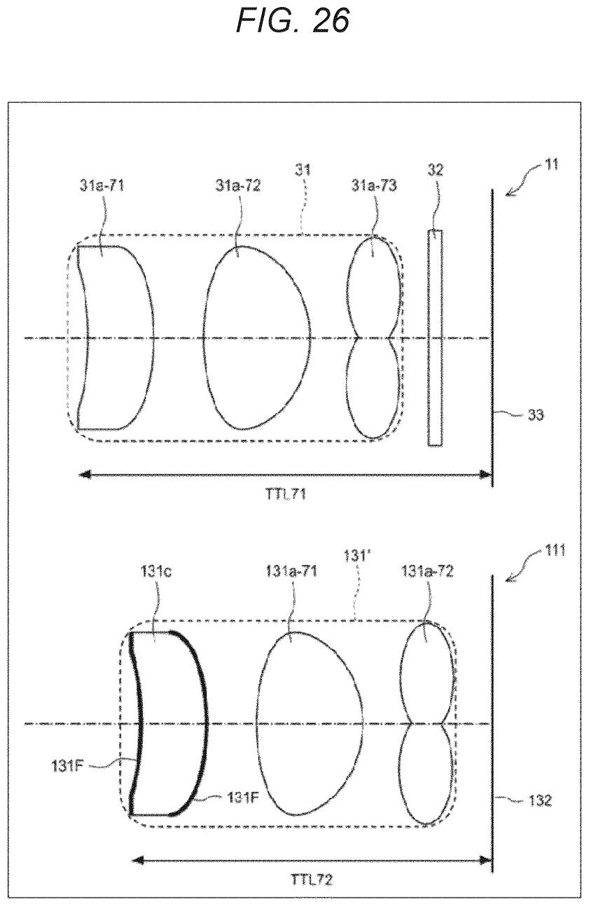

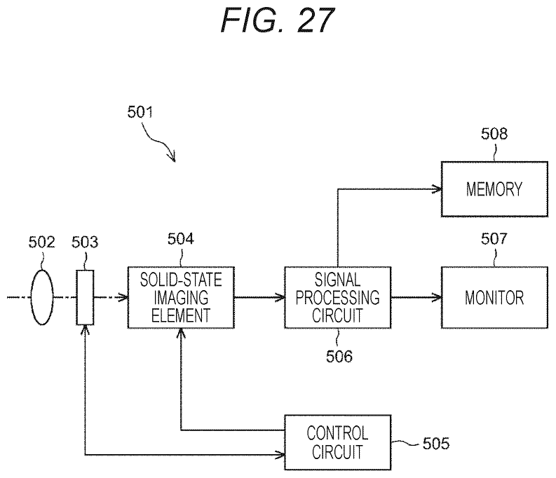

FIG. 26 illustrates a configuration example of a solid-state imaging apparatus 11 with a BPF 32, and a configuration example of a solid-state imaging apparatus 111 without a BPF and including a lens in which a coating that cuts a visible light component and transmits near-infrared light is applied to a part of a lens group 131.

In other words, an example of the solid-state imaging apparatus 11 with the BPF 32 is illustrated in the upper row of FIG. 26. The lens group 31 of the solid-state imaging apparatus 11 includes lenses 31a-71 to 31a-73, the BPF 32 is provided at a subsequent stage of the lenses 31a-71 to 31a-73, and moreover, a solid-state imaging element 33 is provided at a subsequent stage of the BPF 32.

Meanwhile, the configuration example of the solid-state imaging apparatus 111 without the BPF is illustrated in the lower row of FIG. 26, and the lens group 131 includes a coating lens 131c in which a coating 131F that cuts a visible light component and transmits near-infrared light is formed on each of a front surface and a back surface with respect to an incident direction and lenses 131a-71 and 131a-72.

Note that the coating lens 131c is used to cut the visible light component and transmits the near-infrared light by forming the coating 131F on each of the front surface and the back surface with respect to the incident direction, and therefore, the coating lens 131c may include a resin material or may include glass.

With such a configuration, a distance TTL72 from an object-side lens surface top of the lens group 131 to an imaging surface of a solid-state imaging element 132 in the solid-state imaging apparatus 111 without the BPF in FIG. 26 can be made smaller than a distance TTL71 from an object-side lens surface top of the lens group 31 to an imaging surface of a solid-state imaging element 33 in the solid-state imaging apparatus 11 with the BPF in FIG. 26.

As a result, the coating lens 131c coated with the coating 131F is provided at any of the lens constituting the lens group 131, whereby the solid-state imaging apparatus 111 can be configured without the BPF, and downsizing and height reduction of an apparatus configuration can be achieved. In addition, since it is not necessary to provide the BPF, a cost can also be reduced.

Note that although an example in which one in the lens group 131 is the coating lens 131c has been described above, a plurality of lenses 131a in the lens group 131 may be set as the coating lens 131c.

In addition, since the coating lens 131c is not required to have a specific lens shape such as that of a meniscus lens, the degree of freedom of the lens shape can be improved. In particular, the coating lens 131c is effective in cases such as a case where no meniscus lens is present in the lens group 131, a case where only a thick lens is included in the lens group 131.

However, as described with reference to FIG. 5, the coating 131F is formed, whereby a band of the transmitted light shifts according to an angle of incidence in the coating lens 131c, and thus this does not contribute to a wide angle of view.

### 4. Example of Application to Electronic Apparatus

The solid-state imaging apparatuses 111 in FIGS. 4, 11, 15, 19, 23, and 26 described above can be applied to various electronic apparatuses, for example, an imaging apparatus such as a digital still camera or a digital video camera, a mobile phone having an imaging function, or other devices having an imaging function.

FIG. 27 is a block diagram showing a configuration example of an imaging apparatus as an electronic apparatus to which the present technology is applied.

An imaging apparatus 501 illustrated in FIG. 27 includes an optical system 502, a shutter device 503, a solid-state imaging element 504, a drive circuit 505, a signal processing circuit 506, a monitor 507, and a memory 508 and can capture a still image and a moving image.

The optical system 502 includes one or a plurality of lenses, guides light (incident light) from a subject to the solid-state imaging element 504, and forms an image on a light receiving surface of the solid-state imaging element 504.

The shutter device 503 is disposed between the optical system 502 and the solid-state imaging element 504, and controls a light irradiation period and a light shielding period with respect to the solid-state imaging element 504 according to the control of a drive circuit 1005.

The solid-state imaging element 504 includes a package including the solid-state imaging element described above. The solid-state imaging element 504 accumulates signal charges for a certain period according to light formed into an image on the light receiving surface via the optical system 502 and the shutter device 503. The signal charges accumulated in the solid-state imaging element 504 are transferred according to a drive signal (timing signal) supplied from the drive circuit 505.

The drive circuit 505 outputs the drive signal for controlling a transfer operation of the solid-state imaging element 504 and a shutter operation of the shutter device 503 to drive the solid-state imaging element 504 and the shutter device 503.

The signal processing circuit 506 performs various types of signal processing on the signal charges output from the solid-state imaging element 504. An image (image data) obtained by performing the signal processing by the signal processing circuit 506 is supplied to the monitor 507 and displayed or supplied to the memory 508 and stored (recorded).

Also in the imaging apparatus 501 configured as described above, the solid-state imaging apparatus 111 in FIGS. 4, 11, 15, 19, 23, and 26 are applied instead of the optical system 502 and the solid-state imaging element 504 described above, whereby downsizing and height reduction of an apparatus configuration can be achieved. In addition, the solid-state imaging apparatus 111 in FIGS. 4, 11, 15, 19, and 23 is applied instead of the optical system 502 and the solid-state imaging element 504 described above, whereby a wide angle of view can be achieved.

### 5. Usage Example of Solid-State Imaging Apparatus

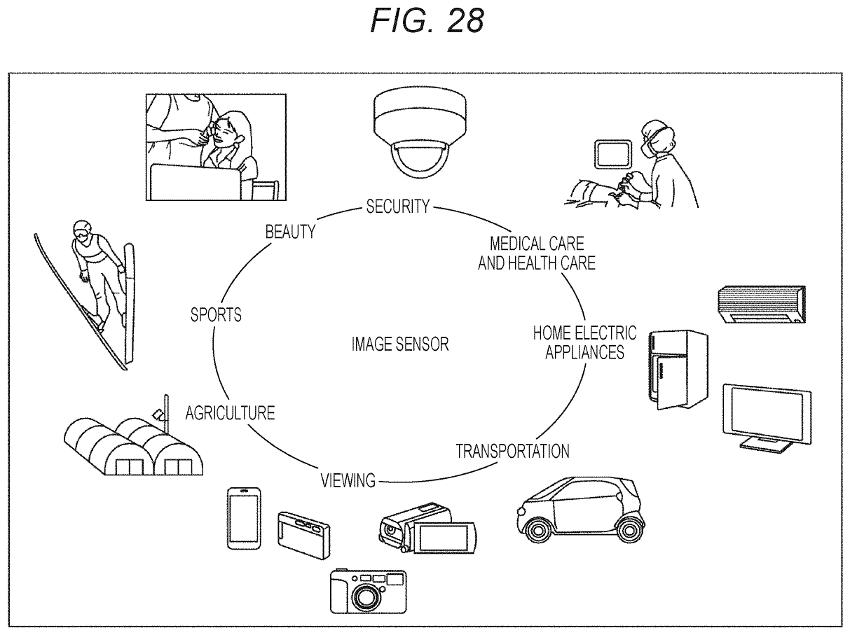

FIG. 28 is a diagram illustrating a usage example of using the solid-state imaging apparatus 111 described above.

The solid-state imaging apparatus 111 described above can be used in various cases in which light such as visible light, infrared light, ultraviolet light, and X-ray is sensed, for example, as described below.
A device that captures an image to be used for viewing, such as a digital camera and a portable device with a camera function
A device for traffic purpose such as an in-vehicle sensor that captures images of the front, rear, surroundings, interior, and the like of an automobile, a monitoring camera for monitoring traveling vehicles and roads, and a ranging sensor that measures a distance between vehicles and the like for safe driving such as automatic stop, recognition of a driver's condition, and the like
A device for home appliance such as a television, a refrigerator, and an air conditioner that captures an image of a user's gesture and performs a device operation according to the gesture
A device used for medical and health care such as an endoscope and a device that performs angiography by receiving infrared light
A device used for security such as a security monitoring camera and an individual authentication camera
A device used for beauty care such as a skin measuring instrument for capturing images of skin and a microscope for capturing images of the scalp
A device used for sport such as an action camera or a wearable camera for sports applications or the like
A device used for agriculture such as a camera for monitoring conditions of fields and crops.

Note that the present disclosure can also have the following configurations.

<1> A solid-state imaging apparatus including:
a solid-state imaging element configured to capture an image including a pixel signal corresponding to a light amount of incident light; and
a lens group including a plurality of lenses configured to condense the incident light and form an image on an imaging surface of the solid-state imaging element, in which
at least one of the plurality of lenses constituting the lens group is a visible light cut lens configured to cut a visible light ray from the incident light and transmit the incident light.

<2> The solid-state imaging apparatus according to <1>, in which
the plurality of lenses is three lenses, four lenses, or two to five lenses.

<3> The solid-state imaging apparatus according to <1> or <2>, in which
the visible light cut lens is a dye lens molded from a resin material including a dye configured to absorb a visible light ray.

<4> The solid-state imaging apparatus according to <3>, in which
in the dye lens, a surface on which the incident light is incident has one of a concave shape and a convex shape and a surface through which the incident light is transmitted and emitted has the other of the concave shape and the convex shape.

<5> The solid-state imaging apparatus according to <3>, in which
the dye lens is a part of the plurality of lenses constituting the lens group.

<6> The solid-state imaging apparatus according to <3>, in which
the dye lens is one of the plurality of lenses constituting the lens group.

<7> The solid-state imaging apparatus according to <3>, in which
the dye lens is a lens among the plurality of lenses constituting the lens group, the lens being such that:
a maximum thickness Tmax is smaller than a first predetermined thickness and a minimum thickness Tmin is larger than a second predetermined thickness; and
a ratio Tmax/Tmin between the maximum thickness Imax and the minimum thickness Imin is smaller than a predetermined value.

<8> The solid-state imaging apparatus according to <7>, in which
the dye lens is a lens among the plurality of lenses constituting the lens group, the lens being such that:
the maximum thickness Tmax is smaller than 1.00 mm and the minimum thickness Tmin is larger than 0.10 mm; and
the ratio Tmax/Imin between the maximum thickness Tmax and the minimum thickness Imin is smaller than 4.0.

<9> The solid-state imaging apparatus according to <7>, in which
the dye lens is a lens among the plurality of lenses constituting the lens group, the lens being such that:
a value (|Vc−Vp|/n) obtained by dividing a difference absolute value |Vc−Vp| between an optical path length Vc of a main light ray at an image height center and an optical path length Vp of the main light ray at an image height of 80% by a refractive index n of a main wavelength is shorter than a predetermined length; and
a value ((Vi_max−Vi_mmin)/n) obtained by dividing a difference (Vi_max−Vi_mmin) between a maximum optical path length Vi_max at an image height of i·10% and a minimum optical path length Vi_min at the image height of i·10% by the refractive index n of the main wavelength is shorter than the predetermined length, and
the i is 0 to 8.

<10> The solid-state imaging apparatus according to <9>, in which
the dye lens is a lens among the plurality of lenses constituting the lens group, the lens being such that:
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm; and
the value ((Vi_max−Vi_mmin)/n) obtained by dividing the difference (Vi_max−Vi_mmin) between the maximum optical path length Vi_max at the image height of i·10% and the minimum optical path length Vi_min at the image height of i·10% by the refractive index n of the main wavelength is shorter than 0.2 mm.

<11> The solid-state imaging apparatus according to <10>, in which
the dye lens is a lens among the plurality of lenses constituting the lens group, the lens being such that:
the ratio Tmax/Tmin between the maximum thickness Imax and the minimum thickness Imin is smaller than 4.0;
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm;
the value ((Vi_max−Vi_mmin)/n) obtained by dividing the difference (Vi_max−Vi_mmin) between the maximum optical path length Vi_max at the image height of i·10% and the minimum optical path length Vi_min at the image height of i·10% by the refractive index n of the main wavelength is shorter than 0.2 mm; and
at least one of the ratio Tmax/Imin, the value (|Vc-Vp|/n), and the value ((Vi_max−Vi_mmin)/n) becomes minimum.

<12> The solid-state imaging apparatus according to <10>, in which
the dye lens is a lens among the plurality of lenses constituting the lens group, the lens being such that:
the ratio Tmax/Tmin between the maximum thickness Imax and the minimum thickness Imin is smaller than 4.0;
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm;
the value ((Vi_max−Vi_mmin)/n) obtained by dividing the difference (Vi_max−Vi_mmin) between the maximum optical path length Vi_max at the
image height of i·10% and the minimum optical path length Vi_min at the image height of i·10% by the refractive index n of the main wavelength is shorter than 0.2 mm; and
a volume of the lens becomes minimum.

<13> The solid-state imaging apparatus according to <1> or <2>, in which
the visible light cut lens is a coding lens in which a coating configured to cut a visible light ray is applied to both an incident surface and an emission surface of the incident light.

<14> The solid-state imaging apparatus according to <13>, in which
the coding lens is obtained by applying the coating configured to cut a visible light ray to both the incident surface and the emission surface of a lens including a transparent resin material or a lens including glass.

<15> An imaging apparatus including a solid-state imaging apparatus, in which
the solid-state imaging apparatus includes:
a solid-state imaging element configured to capture an image including a pixel signal corresponding to a light amount of incident light; and
a lens group including a plurality of lenses configured to condense the incident light and forms an image on an imaging surface of the solid-state imaging element, and
at least one of the plurality of lenses constituting the lens group is a visible light cut lens configured to cut a visible light ray from the incident light and transmit the incident light.

<16> An electronic apparatus including:
a solid-state imaging element configured to capture an image including a pixel signal corresponding to a light amount of incident light; and
a lens group including a plurality of lenses configured to condense the incident light and form an image on an imaging surface of the solid-state imaging element, in which
at least one of the plurality of lenses constituting the lens group is a visible light cut lens configured to cut a visible light ray from the incident light and transmit the incident light.

### REFERENCE SIGNS LIST

11 Solid-state imaging apparatus
31 Lens group
31a, 31a-1 to 31a-3, 31a-11 to 31a-13, 31a-21 to 31a-23 Lens
32 BPF
33 Solid-state imaging element
111 Solid-state imaging apparatus
131 Lens group
131a, 131a-1 to 131a-3, 131a-11 to 131a-13, 131a-21 to 31a-23,
131a-31, 131a-32
131b Dye lens
131c Lens
131F Coating
132 Solid-state imaging element

1. A solid-state imaging apparatus comprising:
a solid-state imaging element configured to capture an image including a pixel signal corresponding to a light amount of incident light; and
a lens group including a plurality of lenses configured to condense the incident light and forms an image on an imaging surface of the solid-state imaging element, wherein
at least one of the plurality of lenses constituting the lens group is a visible light cut lens configured to cut a visible light ray from the incident light and transmit the incident light.

2. The solid-state imaging apparatus according to claim 1, wherein
the plurality of lenses is two to five lenses.

3. The solid-state imaging apparatus according to claim 1, wherein
the visible light cut lens is a dye lens molded from a resin material including a dye configured to absorb a visible light ray.

4. The solid-state imaging apparatus according to claim 3, wherein
in the dye lens, a surface on which the incident light is incident has one of a concave shape and a convex shape and a surface through which the incident light is transmitted and emitted has the other of the concave shape and the convex shape.

5. The solid-state imaging apparatus according to claim 3, wherein
the dye lens is a part of the plurality of lenses constituting the lens group.

6. The solid-state imaging apparatus according to claim 3, wherein
the dye lens is one of the plurality of lenses constituting the lens group.

7. The solid-state imaging apparatus according to claim 3, wherein
the dye lens is a lens among the plurality of lenses constituting the lens group, the lens being such that:
a maximum thickness Tmax is smaller than a first predetermined thickness and a minimum thickness Imin is larger than a second predetermined thickness; and
a ratio Tmax/Tmin between the maximum thickness Tmax and the minimum thickness Imin is smaller than a predetermined value.

8. The solid-state imaging apparatus according to claim 7, wherein
the dye lens is a lens among the plurality of lenses constituting the lens group, the lens being such that:
the maximum thickness Tmax is smaller than 1.00 mm and the minimum thickness Imin is larger than 0.10 mm; and
the ratio Tmax/Tmin between the maximum thickness Tmax and the minimum thickness Tmin is smaller than 4.0.

9. The solid-state imaging apparatus according to claim 7, wherein
the dye lens is a lens among the plurality of lenses constituting the lens group, the lens being such that:
a value (|Vc−Vp|/n) obtained by dividing a difference absolute value |Vc−Vp| between an optical path length Vc of a main light ray at an image height center and an optical path length Vp of the main light ray at an image height of 80% by a refractive index n of a main wavelength is shorter than a predetermined length; and
a value ((Vi_max−Vi_mmin)/n) obtained by dividing a difference (Vi_max−Vi_mmin) between a maximum optical path length Vi_max at an image height of i·10% and a minimum optical path length Vi_min at the image height of i·10% by the refractive index n of the main wavelength is shorter than the predetermined length, and
the i is 0 to 8.

10. The solid-state imaging apparatus according to claim 9, wherein
the dye lens is a lens among the plurality of lenses constituting the lens group, the lens being such that:
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm; and
the value ((Vi_max−Vi_mmin)/n) obtained by dividing the difference (Vi_max−Vi_mmin) between the maximum optical path length Vi_max at the image height of i·10% and the minimum optical path length Vi_min at the image height of i·10% by the refractive index n of the main wavelength is shorter than 0.2 mm.

11. The solid-state imaging apparatus according to claim 10, wherein
the dye lens is a lens among the plurality of lenses constituting the lens group, the lens being such that:
the ratio Tmax/Tmin between the maximum thickness Tmax and the minimum thickness Imin is smaller than 4.0;
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm;
the value ((Vi_max−Vi_mmin)/n) obtained by dividing the difference (Vi_max−Vi_mmin) between the maximum optical path length Vi_max at the image height of i·10% and the minimum optical path length Vi_min at the image height of i·10% by the refractive index n of the main wavelength is shorter than 0.2 mm; and
at least one of the ratio Tmax/Imin, the value (|Vc−Vp|/n), and the value ((Vi_max−Vi_mmin)/n) becomes minimum.

12. The solid-state imaging apparatus according to claim 10, wherein
the dye lens is a lens among the plurality of lenses constituting the lens group, the lens being such that:
the ratio Tmax/Imin between the maximum thickness Tmax and the minimum thickness Imin is smaller than 4.0;
the value (|Vc−Vp|/n) obtained by dividing the difference absolute value |Vc−Vp| between the optical path length Vc of the main light ray at the image height center and the optical path length Vp of the main light ray at the image height of 80% by the refractive index n of the main wavelength is shorter than 0.2 mm;
the value ((Vi_max−Vi_mmin)/n) obtained by dividing the difference (Vi_max−Vi_mmin) between the maximum optical path length Vi_max at the image height of i·10% and the minimum optical path length Vi_min at the image height of i·10% by the refractive index n of the main wavelength is shorter than 0.2 mm; and
a volume of the lens becomes minimum.

13. The solid-state imaging apparatus according to claim 1, wherein
the visible light cut lens is a coding lens in which a coating configured to cut a visible light ray is applied to both an incident surface and an emission surface of the incident light.

14. The solid-state imaging apparatus according to claim 13, wherein
the coding lens is obtained by applying the coating configured to cut a visible light ray to both the incident surface and the emission surface of a lens including a transparent resin material or a lens including glass.

15. An imaging apparatus comprising: a solid-state imaging apparatus wherein
the solid-state imaging apparatus includes:
a solid-state imaging element configured to capture an image including a pixel signal corresponding to a light amount of incident light; and
a lens group including a plurality of lenses configured to condense the incident light and forms an image on an imaging surface of the solid-state imaging element, and
at least one of the plurality of lenses constituting the lens group is a visible light cut lens configured to cut a visible light ray from the incident light and transmit the incident light.

16. An electronic apparatus comprising:
a solid-state imaging element configured to capture an image including a pixel signal corresponding to a light amount of incident light; and
a lens group including a plurality of lenses configured to condense the incident light and form an image on an imaging surface of the solid-state imaging element, wherein
at least one of the plurality of lenses constituting the lens group is a visible light cut lens configured to cut a visible light ray from the incident light and transmit the incident light.
